(19) United States
(12) Patent Application Publication
(10) Pub. No.: US 2008/0175082 A1
(43) Pub. Date: Jul. 24, 2008

(54) SERIAL POWER CAPACITOR DEVICE

(75) Inventor: Yong-Hwan NOH, Gyeonggi-do (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/018,294

(22) Filed: Jan. 23, 2008

(30) Foreign Application Priority Data
Jan. 23, 2007 (KR) 2007-07135

(51) Int. Cl. H04B 1/10; G11C 7/02

(52) U.S. Cl. 365/206; 327/551

(57) ABSTRACT

A serial power capacitor device is provided which includes a noise suppressing circuit which includes a plurality of capacitive elements for suppressing a power noise, and a stabilizing circuit which stabilizes an operation of the noise suppressing circuit by compensating for variations in leakage current of the capacitive elements. The plurality of capacitive elements may, for example, be a plurality of power capacitors connected in series between a power source voltage and a ground voltage, and the stabilizing circuit may, for example, include a plurality of resistors connected in series between the power source voltage and the ground voltage. The resistors may, for example, be connected in parallel to the respective power capacitors, and a resistive value of each of the resistors may, for example, be less than an intrinsic resistive value of the power capacitors, respectively. The capacitive elements may, for example, be formed by DRAM cells or by metal oxide semiconductor (MOS) transistors.

### CROSS-REFERENCE TO RELATED APPLICATIONS

A claim of priority under 35 U.S.C. §119 is made to Korean Patent Application No. 10-2007-0007135, filed Jan. 23, 2007, the entire contents of which are hereby incorporated by reference.

### BACKGROUND OF THE INVENTION

The present invention generally relates to signal noise suppression, and more particularly, the present invention relates to a serial power capacitor device that may be utilized to suppress signal noise.

A capacitor generally includes parallel conductive plates with a dielectric material interposed therebetween. The dielectric material is operationally stable in a given voltage region, and thus the operational stability of the capacitor itself is dependent upon voltage characteristics and dimensions of the dielectric material. When an applied voltage of the capacitor exceeds the given voltage region, the useful life of the capacitor may be reduced or the capacitor may be destroyed. Also, capacitors are non-ideal elements in that the dielectrics thereof are not perfect insulators and thus include an intrinsic resistive component. A resultant leakage current causes capacitors to discharge over time.

In the meantime, semiconductor device generally maintain stable voltage states by utilizing capacitors to suppress power noise. To ensure that the capacitors operate in a stable voltage region, the capacitors are conventionally connected in series to define a serial capacitor device. Generally, a serial capacitor device of this type includes high capacitance capacitors (often referred to as power capacitors) connected in series.

In an ideal case, constant voltages are continuously applied to the respective power capacitors. For example, in the case where two equally sized power capacitors are connected in series to form a serial power capacitor device, a voltage of VDD/2 is continuously applied to each power capacitor (assuming a power voltage of a semiconductor device is VDD).

However, dielectric properties of the power capacitors may deteriorate over time or may exhibit process variations or defects. As a result, leakage current of an affected one of the power capacitors may increase, which in turn can result in a relatively high voltage being applied to the remaining power capacitor(s) of the device. This high voltage may exceed the given voltage region discussed above, thereby causing dielectric damage or breakdown of the remaining power capacitor(s).

### SUMMARY OF THE INVENTION

According to one aspect of the present invention, a serial power capacitor device is provided which includes a noise suppressing circuit which includes a plurality of capacitive elements for suppressing a power noise, and a stabilizing circuit which stabilizes an operation of the noise suppressing circuit by compensating for variations in leakage current of the capacitive elements.

The plurality of capacitive elements may, for example, be a plurality of power capacitors connected in series between a power source voltage and a ground voltage, and the stabilizing circuit may, for example, include a plurality of resistors connected in series between the power source voltage and the ground voltage. The resistors may, for example, be connected in parallel to the respective power capacitors, and a resistive value of each of the resistors may, for example, be less than an intrinsic resistive value of the power capacitors, respectively.

The capacitive elements may, for example, be formed by DRAM cells or by metal oxide semiconductor (MOS) transistors.

### BRIEF DESCRIPTION OF THE DRAWINGS

The figures illustrated in the accompanying drawings are included to provide a further understanding of the present invention, and are incorporated in and constitute a part of this specification. The figures illustrate exemplary embodiments of the present invention and, together with the description, serve to explain principles of the present invention. In the figures:

FIG. 1 is a circuit diagram of a serial power capacitor device according to a first embodiment of the present invention;

FIG. 2 is a view illustrating intrinsic resistors of the power capacitors illustrated in FIG. 1;

FIG. 3 is a circuit diagram of a serial power capacitor device according to a second embodiment of the present invention; and

FIG. 4 is a circuit diagram of a serial power capacitor device according to a third embodiment of the present invention.

### DETAILED DESCRIPTION OF PREFERRED EMBODIMENTS

Preferred but non-limiting embodiments of the present invention will be described below in more detail with reference to the accompanying drawings.

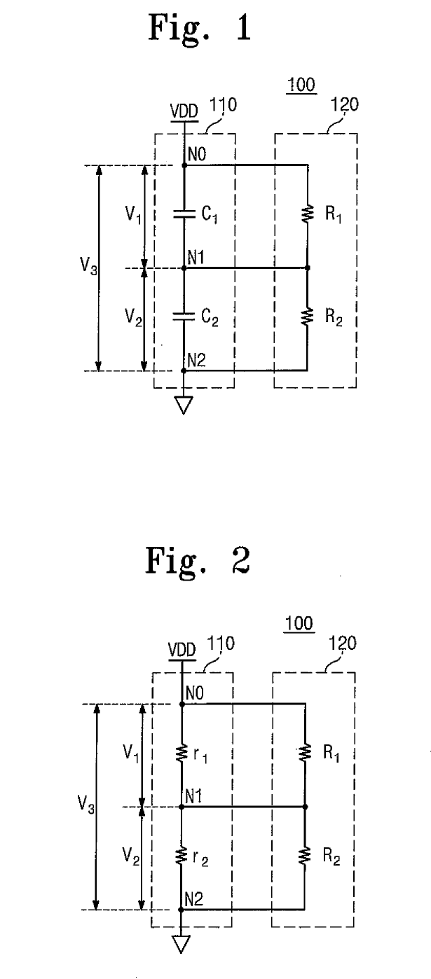

FIG. 1 is a circuit diagram of a serial power capacitor device according to a first embodiment of the present invention.

Referring to FIG. 1, the serial power capacitor device 100 includes a noise suppressing circuit 110 and stabilizing circuit 120. In this example, the noise suppressing circuit 110 includes power capacitors C₁ and C₂ connected in series between nodes N0 and N2, and the stabilizing circuit 120 includes resistors R₁ and R₂ connected in series between nodes N0 and N2. As shown, in this embodiment, node N0 is connected to a power source voltage VDD, and node N2 is connected to a ground voltage. Also, the capacitor C₁ and the resistor R₁ are connected in parallel across nodes N0 and N1, and the capacitor C₂ and the resistor R₂ are connected in parallel across nodes N2 and N1.

In the example of this non-limiting embodiment, the capacitors C1 and C2 are the same size (capacitance), and the resistors R1 and R2 are the same size (resistance). Also, a resistive value (Rs) of each of the resistors R₁ and R₂ is smaller than a respective intrinsic resistive value (rs) of the capacitors C₁ and C₂. That is, Rs<rs.

The power capacitors C₁ and C₂ are high capacitance devices suitable for suppressing power noise. In the example of this embodiment, the power capacitors C₁ and C₂ are the capacitive elements of dynamic random access memory (DRAM) cells of a semiconductor memory device. The noise suppressing circuit 110, having the power capacitors C1 and C2, functions to suppress a power noise of a voltage VDD input to a semiconductor device. As will be explained below, the noise stabilizing circuit 120 stabilizes an operation of the noise suppressing circuit by compensating for variations in leakage current among the power capacitors C₁ and C₂. In this manner, damage to the noise suppressing circuit 110 may be avoided.

When the power capacitors C₁ and C₂ have the same size and properties, the intrinsic resistances of the power capacitors C₁ and C₂ are the same, and voltages applied to the power capacitors are the same. That is, referring to FIG. 1, a voltage V₁ of the power capacitor C₁ is the same as a voltage V₂ of the power capacitor C₂. Therefore, when a potential difference across node N0 and node N2 is V₃, a potential difference V₃/2 (=V₁) is present across node N0 and a node N1, and the potential difference V₃/2 (=V₂) is present across node N1 and node N2.

The dielectrics of the power capacitors C₁ and C₂ have a stable voltage region, and thus the power capacitors C₁ and C₂ also have a stable voltage region dependent upon the properties and size of the dielectrics. If a voltage applied to either power capacitor exceeds the stable voltage region, the power capacitor may be damaged or destroyed. Therefore, the upper limit of the stable voltage region of each of the power capacitors C₁ and C₂ should greater than the potential difference of V₃/2.

However, as discussed in the background section herein, the insulating characteristic of the dielectrics of the power capacitors C₁ and C₂ may deteriorate over time or deviate from one another due to process variations or a defects. Deterioration in insulating characteristic can reduce an intrinsic resistance, which in turn can result in an increase in leakage current. Any relative increase in leakage current of one of the power capacitors C₁ and C₂ will result in an increase in voltage across the other of the power capacitors C₁ and C₂. This is because the intrinsic resistance of the power capacitor C₁ will exceed that of the power capacitor C₂. If the increase voltage across the power capacitor C₁ exceeds the stable voltage range, the power capacitor C₁ may be damaged or destroyed. As discussed next with reference to FIG. 2, the stabilizing circuit 120 functions to mitigate or eliminate this possibility.

FIG. 2 is a view illustrating the intrinsic resistors of the power capacitors illustrated in FIG. 1. That is, the intrinsic resistor r₁ illustrated in FIG. 2 is the intrinsic resistor of the power capacitor C₁ and the intrinsic resistor r₂ is the intrinsic resistor of the power capacitor C₂.

Assume that deterioration or deviation of the insulating characteristic of the dielectric of the power capacitor C₂ has resulted in a relative decrease in the intrinsic resistor r₂. In this case, the intrinsic resistor r₁ has a larger resistance than that of the intrinsic resistor r₂. However, a corresponding imbalance in applied voltages is avoided since the resistors R₁ and R₂ are connected in parallel to the intrinsic resistors r₁ and r₂, respectively. That is, the potential difference V₁ between the node N0 and the node N1, and the potential difference V₂ between the node N1 and the node N2 are maintained at similar levels.

In the absence of the resistors R₁ and R₂, the voltages V1 and V2 applied to the power capacitors C₁ and C₂ of the serial power capacitor device 100, respectively, are as follows:

V₁=(r₁/(r₁+r₂))×V₃ Equation 1

V₂=(r₂/(r₁+r₂))×V₃ Equation 2

In contrast, when the resistors R₁ and R₂ are connected in parallel to the intrinsic resistors r₁ and r₂ of the corresponding capacitors C₁ and C₂, respectively, the voltages V₁ and V₂ applied to the power capacitors C₁ and C₂ of the serial power capacitor device 100, respectively, are as follows:

V₁=(K₁/(K₁+K₂))×V₃ Equation 3

V₂=(K₂/(K₁+K₂))×V₃ Equation 4

In Equations 3 and 4, a composite resistance between the node N0 and the node N1 is K₁=r₁R₁(r₁+R₁), and composite resistance between the node N1 and the node N2 is K₂=r₂R₂(r₂+R₂).

Referring to Equations 1 and 2, it can be seen, for example, that any relative decrease in the intrinsic resistance r₂ of the power capacitor C₂ will substantially increase the potential difference V₁. Likewise, any relative decrease in the intrinsic resistance r₁ of the power capacitor C₁ will substantially increase the potential difference V₂.

In contrast, as can be seen from Equations 3 and 4, any relative difference between the intrinsic resistors r₁ and r₂ of the power capacitors C₁ and C₂ has less of an impact on the relative difference between the voltages V₁ and V₂. This is especially the case where the resistors R₁ and R₂ have resistances which are smaller than those of the intrinsic resistors r₁ and r₂ of the power capacitors C₁ and C₂. Preferably, the ideal (specified) resistive values of the intrinsic resistors r₁ and r₂ of the power capacitors C₁ and C₂ is at least 10 times greater than the resistive values of the resistors R₁ and R₂, and more preferably, at least 100 times greater.

By way of example, assume that the intrinsic resistor r₁ has a resistance of 1 MΩ, the intrinsic resistor r₂ has resistance of a 0.1 MΩ (due to deterioration of insulating properties), the resistors R₁ and R₂ have a resistance of 10 kΩ, and the voltage V₃ is 2 V.

Applying these assumed values to Equations 1 and 2, the potential difference V₁ between the node N0 and the node N1 becomes (1 M/1.1 M)/×2=1.818 V, and the potential difference V₂ between the node N1 and the node N2 becomes (0.1 M/1.1 M)×2=0.22 V.

When the assumed values are applied to Equations 3 and 4, the composite resistance K₁ between the node N0 and the node N1 becomes (10 M/1.0 M)≈10(Ω), and the composite resistance K2 between the node N1 and the node N2 becomes (1 M/0.1 M)≈10(Ω). Therefore, the potential difference V₁ between the node N0 and the node N1, and the potential difference V₂ between the node N1 and the node N2 are both approximately 1 V.

As described above, according to the example of FIG. 1, the power capacitors C₁ and C₂ are respectively connected in parallel to the resistors R₁ and R₂ of the stabilizing circuit 120, and the resistors R₁ and R₂ have resistances which are smaller than the intrinsic resistances of the power capacitors C₁ and C₂. As a result, the potential difference V₁ between the node N0 and the node N1 and the potential difference V₂ between the node N1 and the node N2 are maintained at similar levels even upon a relative increase in leakage current of one of the power capacitors C₁ and C₂. In this manner, damage to the power capacitors C₁ and C₂ may be avoided.

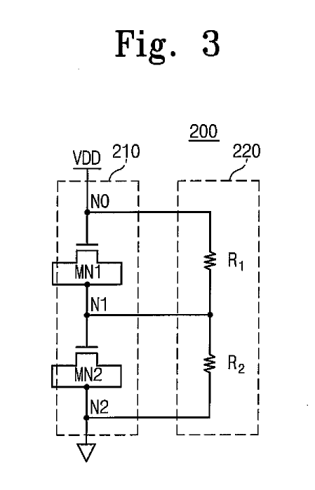

FIG. 3 is a circuit diagram of a serial power capacitor device according to a second embodiment of the present invention.

Referring to FIG. 3, the serial power capacitor device 200 of this example includes a noise suppressing circuit 210 and a noise suppressing circuit stabilizing unit 220. The noise suppressing circuit 210 includes two NMOS transistors MN1 and MN2, and the noise suppressing circuit stabilizing unit 220 includes two resistors R₁ and R₂.

The serial power capacitor device 200 of FIG. 3 is similar in configuration and function to that of FIG. 1, except that the power capacitors C₁ and C₂ are formed by the NMOS transistors MN1 and MN2. In particular, source and drain of each of the NMOS transistors MN1 and MN2 are connected to each other as shown to define capacitive elements which are connected in series between nodes N0 and N2.

It will be understood that the serial power capacitor device 200 of FIG. 3 may instead include PMOS transistors connected in a reverse direction between VDD and ground relative to the NMOS transistors.

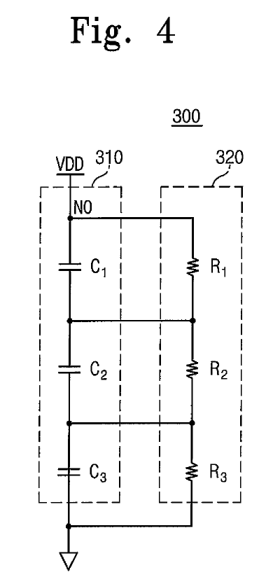

The embodiments of FIG. 1 and 3 include two capacitive elements connected in series. However, the invention is not limited in this respect, and three or more capacitive elements connected in series may be utilized. For example, FIG. 4 is a circuit diagram of a serial power capacitor device which includes three capacitive elements according to a third embodiment of the present invention.

Referring to FIG. 4, the serial power capacitor device 300 includes a noise suppressing circuit 310 and a noise suppressing circuit stabilizing unit 320. The noise suppressing circuit 310 includes three capacitors C₁, C₂, and C₃, and the noise suppressing circuit stabilizing unit 320 includes three resistors R₁, R₂, and R₃.

The serial power capacitor device 300 of FIG. 4 is similar in configuration and function to that of FIG. 1, except that three capacitors C₁, C₂, and C₃ are connected in series and are used to divide a potential difference between a node N0 and a node N3. The three capacitors C₁, C₂, and C₃ are connected in parallel to three corresponding resistors R₁, R₂, and R₃, respectively, to thereby stabilize the relative voltages across the three capacitors C₁, C₂, and C₃.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A serial power capacitor device comprising:
a noise suppressing circuit which includes a plurality of capacitive elements for suppressing a power noise; and
a stabilizing circuit which stabilizes an operation of the noise suppressing circuit by compensating for variations in leakage current of the capacitive elements.

2. The serial power capacitor device of claim 1, wherein the plurality of capacitive elements are a plurality of power capacitors connected in series between a power source voltage and a ground voltage.

3. The serial power capacitor device of claim 2, wherein the stabilizing circuit comprises a plurality of resistors connected in series between the power source voltage and the ground voltage.

4. The serial power capacitor device of claim 3, wherein the resistors are connected in parallel to the respective power capacitors.

5. The serial power capacitor device of claim 3, wherein a resistive value of each of the resistors is less than an intrinsic resistive value of the power capacitors, respectively.

6. The serial power capacitor device of claim 1, wherein the capacitive elements are a plurality of metal oxide semiconductor (MOS) transistor capacitors connected in series between a power source voltage and a ground voltage.

7. The serial power capacitor device of claim 6, wherein the stabilizing circuit comprises a plurality of resistors connected in series between the power source voltage and the ground voltage, and wherein the resistors are connected in parallel to the respective MOS transistor capacitors.

8. The serial power capacitor device of claim 7, wherein a resistive value of each of the resistors is less than an intrinsic resistive value of the MOS transistor capacitors, respectively.

9. The serial power capacitor device of claim 1, wherein the capacitive elements are a plurality of dynamic random access memory (DRAM) cells connected in series between a power source voltage and a ground voltage.

10. The serial power capacitor device of claim 9, wherein the stabilizing circuit comprises a plurality of resistors connected in series between the power source voltage and the ground voltage, and wherein the resistors are connected in parallel to the respective DRAM cells.

11. The serial power capacitor device of claim 10, wherein a resistive value of each of the resistors is less than an intrinsic resistive value of the DRAM cells, respectively.
